(19) United States
(12) Patent Application Publication
(10) Pub. No.: US 2025/0076393 A1
(43) Pub. Date: Mar. 6, 2025

(54) APPARATUS FOR DIAGNOSING BATTERY OF VEHICLE, BATTERY DIAGNOSTIC METHOD THEREOF, AND VEHICLE SYSTEM COMPRISING SAME

(71) Applicants: Hyundai Motor Company, Seoul (KR); Kia Corporation, Seoul (KR)

(72) Inventor: Jung Hyun LEE, Yongin-si (KR)

(21) Appl. No.: 18/612,482

(22) Filed: Mar. 21, 2024

(30) Foreign Application Priority Data
Sep. 4, 2023 (KR) 10-2023-0117152

(51) Int. Cl. G01R 31/3835; B60L 58/15; G01R 31/392; G01R 31/396

(52) U.S. Cl. CPC G01R 31/3835; G01R 31/392; G01R 31/396; B60L 58/15

(57) ABSTRACT

The disclosure relates to an apparatus for diagnosing a battery of a vehicle, that may perform reliable diagnosis with respect to a voltage deviation of a battery of a vehicle, a battery diagnostic method thereof, and a vehicle system including the same. The apparatus for diagnosing a battery of a vehicle may include a voltage sensor measuring voltage with respect to a plurality of battery cells in the battery, and a processor diagnosing a voltage deviation of battery on the basis of the cell voltage measured by the voltage sensor. When the cell voltage deviation satisfies a voltage deviation diagnosis start condition, the processor determines whether or not the cell voltage satisfies a normal voltage range, and in response to a determination result, the processor may diagnose occurrence of a voltage deviation in abnormal cell voltage or occurrence of a voltage deviation in a normal cell voltage.

### CROSS REFERENCE TO RELATED APPLICATIONS

The present application claims priority to Korean Patent Application No. 10-2023-0117152, filed Sep. 4, 2023, the entire contents of which is incorporated herein for all purposes by reference.

### TECHNICAL FIELD

The present disclosure relates to an apparatus for diagnosing a battery and, more particularly, to an apparatus for diagnosing a battery of a vehicle, the apparatus being capable of performing reliable diagnosis with respect to a voltage deviation of a battery of a vehicle, a battery diagnostic method thereof, and a vehicle system including the same.

### BACKGROUND

Since a plurality of battery cells, which are secondary batteries, make up one pack, and multiple packs thereof make up one large capacity battery, it is more important to keep a battery safer for electric vehicles than for general portable electric products.

Moreover, abnormal deterioration of a battery that occurs during high-load driving causes low voltage due to a sharp drop in battery voltage. Continuous use of a battery in such a low voltage state causes over-discharge and intensified cell swelling, and is presumed to be one of the causes of fires in operating of electric vehicles.

Therefore, the safety of a vehicle can be improved only when an accurate diagnosis of voltage drop due to excessive cell deterioration is made.

The current voltage deviation diagnosis technology performs diagnosis with respect to voltage deviation when the difference between the maximum cell voltage and the minimum cell voltage exceeds 1V and the minimum cell voltage is equal to or less than a cell lower limit voltage, or when the maximum cell voltage exceeds a cell upper limit voltage and is maintained for 5 seconds.

However, the rate of voltage drop that occurs when a battery cell is excessively deteriorated is fast, so battery cell voltage enters a voltage sensing abnormality range (less than 0.5V) before 5 seconds. Accordingly, in vehicle driving evaluation, it was confirmed that the current voltage deviation diagnosis technology has limitations in diagnosing voltage deviation in a voltage drop situation that occurs when excessive cell deterioration occurs for the above reasons.

In addition, sharp drop in voltage that occurs in a state of excessive deterioration of battery cells does not meet diagnostic conditions of a logic that diagnoses voltage sensing abnormalities (voltage sensing abnormality diagnosis logic) when a state of less than 0.5V is maintained for 30 seconds.

Therefore, since sharp drop in voltage that occurs when the battery cell is excessively deteriorated is not diagnosed by the voltage deviation diagnosis logic and the voltage sensing abnormality diagnosis logic, and thus the vehicle continues to drive, which may cause a fire.

Likewise, in order to ensure the safety of electric vehicles, technology is required to effectively diagnose voltage deviation even in a situation where battery voltage sharply drops.

### SUMMARY

The present disclosure is directed to an apparatus for diagnosing a battery of a vehicle, the apparatus being capable of performing precise and reliable diagnosis with respect to a voltage deviation even when voltage suddenly drops due to abnormal deterioration of the battery, a battery diagnostic method thereof, and a vehicle system including the same.

Another objective of the present disclosure is to provide an apparatus for diagnosing a battery, the apparatus being capable of diagnosing a voltage deviation in both cases when cell voltage is at a normal level and when cell voltage is at an abnormal level, a battery diagnostic method thereof, and a vehicle system including the same.

Yet another objective of the present disclosure is to provide an apparatus for diagnosing a battery, the apparatus being capable of preciseness and reliability of voltage deviation diagnosis by performing diagnosis with respect to a voltage deviation on the basis of diagnostic conditions differently preset for each of cases when cell voltage is in a normal level and when cell voltage is at an abnormal level, a battery diagnostic method thereof, and a vehicle system including the same.

Still another objective of the present disclosure is to provide an apparatus for diagnosing a battery, the apparatus being capable of performing appropriate following-up measures (or response) to a situation by differently controlling output limitation with respect to a voltage deviation diagnosed when cell voltage is at a normal level and a voltage deviation diagnosed when cell voltage is at an abnormal level, a battery diagnostic method thereof, and a vehicle system including the same.

The technical problem to be achieved in the present disclosure is not limited to the abovementioned, and other problem intended by the present disclosure will be clearly understood by those skilled in the art from the description below.

As a technical means for achieving the above-described technical objectives, there may be provided an apparatus for diagnosing a battery of a vehicle, the apparatus being capable of performing precise and reliable diagnosis with respect to voltage deviation of the battery, a battery diagnostic method thereof, and a vehicle system including the same.

There may be provided the battery diagnostic apparatus that may diagnose voltage deviation with respect to both of when the cell voltage is at a normal level and when the cell voltage is at an abnormal level, the battery diagnostic method thereof, and the vehicle system including the same.

In some implementations, the apparatus for diagnosing a battery of a vehicle may include: a voltage sensor measuring voltage with respect to a plurality of battery cells in the battery; and a processor diagnosing a voltage deviation with respect to the battery on the basis of the cell voltage measured by the voltage sensor.

When the cell voltage deviation satisfies a voltage deviation diagnosis start condition, the processor may determine whether or not the cell voltage satisfies a normal voltage range, and in response to a determination result, the processor may diagnose occurrence of a voltage deviation in abnormal cell voltage or occurrence of a voltage deviation in a normal cell voltage.

When the cell voltage deviation is equal to or greater than a preset reference voltage deviation, the processor may determine whether or not the cell voltage satisfies the normal voltage range.

When a minimum cell voltage exceeds a lower limit threshold voltage or a maximum cell voltage is less than an upper limit threshold voltage, the processor may determine that the cell voltage satisfies the normal voltage range.

In case where the cell voltage does not satisfy the normal voltage range, when the processor determines that situation where the cell voltage deviation satisfies the voltage deviation diagnosis start condition is maintained for a preset first reference time or more, the processor may diagnose that a voltage deviation occurs in the battery.

In case where the cell voltage satisfies the normal voltage range, when the processor determines that situation where the cell voltage deviation meets the voltage deviation diagnosis start condition is maintained for a preset second reference time or more, the processor may diagnose that a voltage deviation occurs in the battery.

When a voltage deviation occurs in the abnormal cell voltage and when a voltage deviation occurs in the normal cell voltage, the processor may limit output power of the battery as different power limits.

A power limit when a voltage deviation occurs in the normal cell voltage may be greater than a power limit when a voltage deviation occurs in the abnormal cell voltage.

The vehicle battery diagnostic method performed by a processor on the basis of a plurality of cell voltages measured by a voltage sensor may include: monitoring the plurality of cell voltages; determining whether or not cell voltage deviation satisfies a voltage deviation diagnosis start condition; determining, when the cell voltage deviation satisfies the voltage deviation diagnosis start condition, whether or not cell voltage satisfies a normal voltage range; and diagnosing, in response to a determination result, whether or not a voltage deviation occurs in an abnormal cell voltage or whether or not a voltage deviation occurs in a normal cell voltage.

The determining of whether or not the voltage deviation diagnosis start condition is satisfied may include determining, when the cell voltage deviation is equal to or greater than a preset reference voltage deviation, that the cell voltage deviation satisfies the voltage deviation diagnosis start condition.

The determining whether or not cell voltage satisfies the normal voltage range may be performed by determining, when a minimum cell voltage exceeds a lower limit threshold voltage or a maximum cell voltage is less than an upper limit threshold voltage, that the cell voltage satisfies the normal voltage range.

The diagnosing may include diagnosing, in case where the cell voltage does not satisfy the normal voltage range, when a situation where the cell voltage deviation satisfies the voltage deviation diagnosis start condition is maintained for a preset first reference time or more, that a voltage deviation occurs in the battery.

The diagnosing may include diagnosing, in case where the cell voltage satisfies the normal voltage range, when it is determined that a situation where the cell voltage deviation satisfies the voltage deviation diagnosis start condition is maintained for a preset second reference time or more, that a voltage deviation occurs in the battery.

The vehicle battery diagnostic method may include: limiting, when diagnosing occurrence of a voltage deviation in the abnormal cell voltage, output power of the battery as a first power limit, and when diagnosing occurrence of a voltage deviation in the normal cell voltage, output power of the battery as a second power limit.

The second power limit has a larger value than a value of the first power limit.

A vehicle system may include: a battery; and a battery diagnostic apparatus.

Specific details according to various examples of the present disclosure, other than the solutions mentioned above, are included in the description and the drawings below.

In some implementations, there can be provided the apparatus for diagnosing a battery of a vehicle, the apparatus being capable of performing precise and reliable diagnosis with respect to a voltage deviation even when voltage suddenly drops due to abnormal deterioration of the battery, the battery diagnostic method thereof, and the vehicle system including the same.

Furthermore, there can be provided the apparatus for diagnosing a battery, the apparatus being capable of diagnosing a voltage deviation in both cases when cell voltage is at a normal level and when cell voltage is at an abnormal level, the battery diagnostic method thereof, and the vehicle system including the same.

Furthermore, there can be provided the apparatus for diagnosing a battery, the apparatus being capable of performing diagnosis with respect to the voltage deviation on the basis of the diagnostic conditions differently preset for when cell voltage is at the normal level and when cell voltage is at the abnormal level, the battery diagnostic method thereof, and the vehicle system including the same.

Furthermore, there can be provided the apparatus for diagnosing a battery, the apparatus being capable of performing appropriate following-up measures (or response) to a situation by differently controlling output limitation with respect to a voltage deviation diagnosed when cell voltage is at the normal level and a voltage deviation diagnosed when cell voltage is at the abnormal level, the battery diagnostic method thereof, and the vehicle system including the same.

In some implementations, the present disclosure can diagnose a voltage deviation not to be a diagnostic object in the conventional voltage deviation diagnosis technology, and can improve precision and reliability of the voltage deviation diagnosis.

Accordingly, the voltage deviation diagnosis technology can prevent over-discharge and intensified cell swelling, and can ensure the safety of electric vehicles by preventing fire occurrence.

The effect of the present disclosure is not limited to the abovementioned, and other effects not mentioned will be clearly understood by those skilled in the art from the description below.

Since the contents of the objectives to be solved, the solution for the objectives, and the effects mentioned above do not specify the essential features of the claims, the right scope of the claims is not limited by the matters described in the contents of the present disclosure.

### BRIEF DESCRIPTION OF THE DRAWINGS

FIG. 1 is a diagram illustrating an example of a vehicle system.

FIG. 2 is a diagram illustrating an example of a battery diagnostic apparatus.

FIG. 3 is a diagram illustrating an example of a vehicle battery diagnostic method.

### DETAILED DESCRIPTION

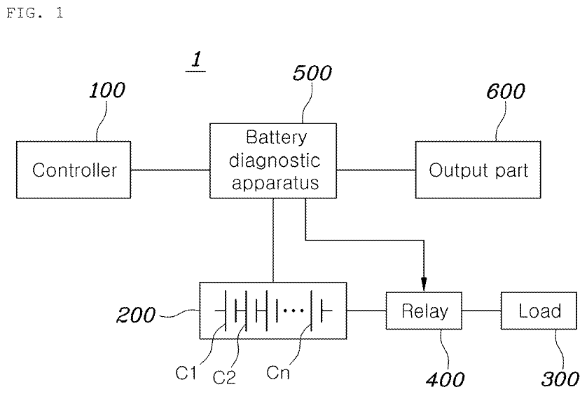

FIG. 1 is a view showing configuration of a vehicle system 1.

Referring to FIG. 1, the vehicle system 1 may include a controller 100, a battery 200, a load 300, a relay 400, a battery diagnostic apparatus 500, and an output part 600, and configuration of the vehicle system 1 is not limited thereto.

In some implementations, the vehicle system 1 may be applied to an electric vehicle, and as an example of an electric vehicle, EV (Electric Vehicle), HEV (Hybrid Electric Vehicle), PHEV (Plug-in Hybrid Electric Vehicle), fuel cell vehicles, etc.

The controller 100 controls overall operation of a vehicle, for example, may be implemented as a vehicle control unit (VCU).

In some implementations, the controller 100 may output information about vehicle conditions (vehicle condition information). For example, when a vehicle is in a power-ON condition, the controller 100 may output a vehicle power ON signal (IG_ON).

The controller 100 may receive related information to the battery 200 through communication of the battery diagnostic apparatus 500 (battery information), and may control operation of the vehicle on the basis of the battery information.

The controller 100 may receive a battery diagnostic result from the battery diagnostic apparatus 500, and may perform a following-up measures according to diagnosis. For example, the controller 100 may output an abnormal diagnosis through a warning system. For example, the warning system may include a display system, a sound system, a warning lamp, etc.

The battery 200 may be a high voltage battery of a vehicle to supply energy to the load 300 generating power of the vehicle, or to be charged by receiving energy by recovery of the load 300.

The battery 200 may include a plurality of battery cells (C1 to Cn). The plurality of battery cells (C1 to Cn) may be implemented in one module (battery module), and the battery 200 may be implemented in a pack form including a plurality of battery modules. For example, the battery 200 may be expressed in ‘a battery module’ or ‘a battery pack’.

The load 300 may be a motor system generating power of a vehicle with energy supplied from the battery 200. For example, the load 300 may include an inverter converting power supplied from the battery 200 into power suitable for a driving motor, and the driving motor driven based on power supplied from the inverter and generating power.

The relay 400 may be disposed between the battery 200 and the load 300. For example, the relay 400 may be disposed on a power movement path between the battery 200 and the load 300.

In some implementations, the relay 400 may be switched according to control of the battery diagnostic apparatus 500. The relay 400 may allow power movement between the battery 200 and the load 300 at turn-on, and may block power movement between the battery 200 and the load 300 at turn-off.

The battery diagnostic apparatus 500 may be performed diagnosis with respect to the battery 200 on the basis of monitoring the battery 200.

For example, the battery diagnostic apparatus 500 may be implemented by a battery management system (BMS). For example, the battery diagnostic apparatus 500 may perform a battery diagnosis algorithm when receiving the vehicle power ON signal (IG_ON) from the controller 100.

In some implementations, the battery diagnostic apparatus 500 may monitor voltages of battery cells (C1 to Cn) in the battery 200 (battery cell voltage or cell voltage), and may perform a voltage deviation diagnosis on the basis of the battery cell voltages.

In some cases, when the battery diagnostic apparatus 500 determines abnormality diagnosis with respect to the battery 200, i.e., when the battery diagnostic apparatus 500 diagnoses that abnormality occurs in the battery 200, the battery diagnostic apparatus 500 may turn off the relay 400.

When the battery diagnostic apparatus 500 diagnoses that abnormality occurs in the battery 200, the battery diagnostic apparatus 500 may provide an abnormality diagnosis result to the output part 600.

The battery diagnostic apparatus 500 may provide a diagnostic result (including an abnormality diagnostic result) with respect to the battery 200 to the controller 100.

The output part 600 may output the abnormality diagnostic result provided from the battery diagnostic apparatus 500 in a preset method.

For example, the output part 600 may include the display system, the sound system, the warning lamp, etc. so as to output abnormality diagnosis with combination of graphics, text, voice, and warning light indicators. These configurations may be provided in a vehicle cluster, or may be provided outside a vehicle cluster.

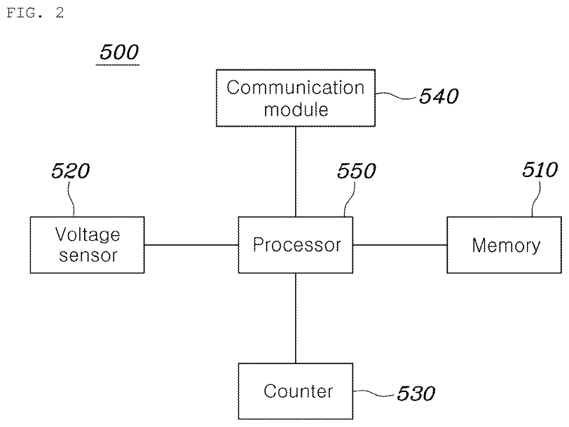

FIG. 2 is a view showing configuration of the battery diagnostic apparatus 500.

In some implementations, the battery diagnostic apparatus 500 may be implemented so as to diagnose a voltage deviation with respect to the battery 200.

Furthermore, the battery diagnostic apparatus 500 may be implemented to diagnose a voltage deviation when cell voltage is at both of a normal level and an abnormal level.

Furthermore, the battery diagnostic apparatus 500 may be implemented to differently control output limitation with respect to each of a voltage deviation diagnosed when cell voltage is in the normal level and a voltage deviation diagnosed when cell voltage is abnormal level.

Referring to FIGS. 1 and 2, the battery diagnostic apparatus 500 may include a memory 510, a voltage sensor 520, a counter 530, a communication module 540, and a processor 550 (or diagnosis processor), configuration of the battery diagnostic apparatus 500 is not limited thereto.

The memory 510 may store algorithm (or program) required for the processor 550 to perform diagnosis for the battery 200, a preset reference value, algorithm of a following-up measure (or response) when abnormality is diagnosed, etc.

The voltage sensor 520 may be connected to an output terminal of the battery 200 and measure a voltage (a battery voltage) output from the battery 200.

The voltage sensor 520 may measure a voltage (battery cell voltage or cell voltage) of each of the plurality of battery cells C1 to Cn in the battery 200. For example, the voltage sensor 520 may be disposed at the side of the battery 200.

The voltage sensor 520 may provide a battery voltage, a battery cell voltage (or cell voltage) to the processor 550. For example, the voltage sensor 520 may perform communication with the processor 550 by a communication method such serial as peripheral interface (SPI) communication in the daisy-chain method, controller area network (CAN) communication, local interconnect network (LIN) communication.

The counter 530 performs count operation according to control of the processor 550, and may output a count signal to the processor 550 for each preset period (e.g., 0.1 second).

The counter 530 may be used when the processor 550 determines time for a predetermined voltage to be maintained.

The communication module 540 may be provided for communication with the controller 100. For example, the communication module 540 may receive vehicle condition information transmitted from the controller 100, and may transmit the received vehicle condition information to the processor 550. At this point, the vehicle condition information may include the vehicle power ON signal (IG_ON).

The communication module 540 may transmit battery information transmitted from the processor 550 (including a battery voltage, a battery cell voltage, etc.), the battery diagnosis result information, etc. to the controller 100.

The processor 550 performs overall operation of the battery diagnostic apparatus 500, and may perform diagnosis with respect to the battery 200. In some implementations, the processor 550 may diagnose a voltage deviation of the battery 200.

The processor 550 may perform diagnosis with respect to the battery 200 one the basis of the algorithm, the reference values, etc. stored in the memory 510. The processor 550 may monitor a plurality of battery cell voltages Vc provided from the voltage sensor 520.

When receiving the vehicle power ON signal (IG_ON) from the controller 100, the processor 550 may start monitoring and diagnosis with respect to the battery 200.

First, the processor 550 may determine whether or not cell voltage deviation satisfies the voltage deviation diagnosis start condition. In some implementations, the processor 550 may determine whether or not cell voltage deviation is equal to or greater than the reference voltage deviation.

For example, the reference voltage deviation may be preset as a value for diagnosis with respect to a voltage deviation to be performed before low voltage diagnosis (diagnosing a situation when a voltage is less than 1.5V). Accordingly, the reference voltage deviation may be preset as 500 mV. However, a value of the reference voltage deviation is not limited thereto, and the reference voltage deviation may have a value from 100 mV to 1V.

When cell voltage deviation does not satisfy the voltage deviation diagnosis start condition, i.e., when cell voltage deviation is less than the reference voltage deviation, the processor 550 may continue to monitor cell voltage.

When cell voltage deviation satisfies the voltage deviation diagnosis start condition, i.e., when cell voltage deviation is equal to or greater than the reference voltage deviation, the processor 550 may determine whether or not cell voltage satisfies the normal voltage range.

In some implementations, the processor 550 may determine whether, among the plurality of cell voltages Vc, a minimum cell voltage Vc_min exceeds a lower limit threshold voltage or a maximum cell voltage Vc_max exceeds an upper limit threshold voltage.

At this point, when the minimum cell voltage Vc_min exceeds the lower limit threshold voltage or the maximum cell voltage Vc_max is less than the upper limit threshold voltage, the processor 550 determines that cell voltage Vc satisfies the normal voltage range.

Furthermore, when the minimum cell voltage Vc_min is equal to or less than the lower limit threshold voltage or the maximum cell voltage Vc_max is equal to or greater than the upper limit threshold voltage, the processor 550 may determine that cell voltage Vc does not satisfy the normal voltage range.

For example, the lower limit threshold voltage and the upper limit threshold voltage may be preset within a battery driving voltage range. For example, the lower limit threshold voltage may be preset within a range of from 2.0V to 2.5V, and the upper limit threshold voltage may be preset within a range of from 4.18V to 4.2V.

When the processor 550 determines that the cell voltage Vc does not satisfy the normal voltage range, the processor 550 may determine whether or not a situation where the cell voltage deviation is equal to or greater than the reference voltage deviation is maintained for a preset first reference time t_ref1 or more.

In some implementations, when the processor 550 determines that the cell voltage Vc does not satisfy the normal voltage range, the processor 550 operates the counter 530, on the basis of the count signal output from the counter 530, may determine whether or not the situation where the cell voltage deviation is equal to or greater than the reference voltage deviation is maintained for the first reference time t_ref1 or more.

For example, the first reference time t_ref1 may be preset considering a reference time of entering the low voltage diagnosis. For example, the first reference time t_ref may be preset as 1 second, and is not limited thereto.

When a situation where the cell voltage deviation is equal to or greater than the reference voltage deviation is maintained for less than the first reference time t_ref1, the processor 550 may determine whether or not the cell voltage Vc satisfies the normal voltage range.

When the situation where the cell voltage deviation is equal to or greater than the reference voltage deviation is maintained for the first reference time t_ref1 or more, the processor 550 diagnoses that a voltage deviation occurs in the battery 200.

As described above, when the processor 550 diagnoses that a voltage deviation occurs when the cell voltage Vc is at the abnormal level, the processor 550 may limit output power of the battery 200 at a first power limit.

At this point, the first power limit may be preset at power by which acceleration is not possible, minimum highway speed may be maintained but it is difficult to maintain continuous highway driving. For example, the first power limit may be preset at 10 Kw but is not limited thereto.

Furthermore, the processor 550 may provide a voltage deviation diagnosis result to the output part 600 and may allow the output part 600 to output an alarm corresponding to the voltage deviation diagnosis result. Furthermore, the processor 550 may provide a voltage deviation diagnosis result to the controller 100 through the communication module 540.

Meanwhile, when the processor 550 determines that the cell voltage Vc satisfies the normal voltage range, the processor 550 may determine whether or not a situation where cell voltage deviation is equal to or greater than the reference voltage deviation is maintained for a preset second reference time t_ref2.

In some implementations, when the processor 550 determines that the cell voltage Vc satisfies the normal voltage range, the processor 550 may operate the counter 530 and, on the basis of a count signal output from the counter 530, the situation where the cell voltage deviation is equal to or greater than the reference voltage deviation is maintained for the second reference time t_ref2 or more.

When the situation where the cell voltage deviation is equal to or greater than the reference voltage deviation is maintained for less than the second reference time t_ref2, the processor 550 may determine whether or not the cell voltage deviation is equal to or greater than the reference voltage deviation.

When the situation where the cell voltage deviation is equal to or greater than the reference voltage deviation is maintained for the second reference time t_ref2 or more, the processor 550 diagnoses that a voltage deviation occurs in the battery 200.

As described above, when the processor 550 diagnoses that a voltage deviation occurs when the cell voltage Vc is at the normal level, the processor 550 may limit output power of the battery 200 at a second power limit.

At this point, the second power limit may be preset at power by which acceleration is impossible and highway driving is possible. For example, the second power limit may be preset at 20 Kw but is not limited thereto.

In some implementations, the second power limit, which is preset as output limit power according to voltage deviation diagnosis when cell voltage satisfies the normal voltage range, may have a value larger than a value of the first power limit, which is preset as output limit power according to voltage deviation diagnosis when cell voltage satisfies the abnormal voltage range.

Furthermore, the processor 550 may provide a voltage deviation diagnosis result to the output part 600 and may allow the output part 600 to output an alarm corresponding to the voltage deviation diagnosis result. Furthermore, the processor 550 may provide a voltage deviation diagnosis result to the controller 100 through the communication module 540.

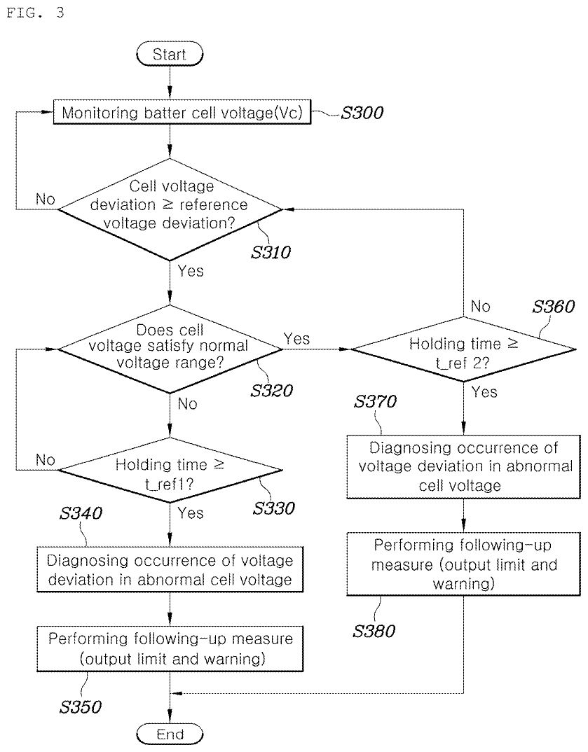

FIG. 3 is a view showing a vehicle battery diagnostic method.

Phased operations shown in FIG. 3 may be performed by the apparatus 500 for diagnosing a battery of a vehicle, described with reference to FIGS. 1 and 2.

Referring to FIGS. 1 to 3, the battery diagnostic apparatus 500 may monitor a battery cell voltage Vc on the basis of a battery cell voltage Vc measured using the voltage sensor 520, at S300.

For example, when receiving the vehicle power ON signal IG_ON provided from the controller 100, the battery diagnostic apparatus 500 may start monitoring the battery cell voltage Vc.

Thereafter, the battery diagnostic apparatus 500 may determine whether or not cell voltage deviation satisfies the voltage deviation diagnosis start condition, at S310.

In S310, when the cell voltage deviation is equal to or greater than the reference voltage deviation, the battery diagnostic apparatus 500 may determine that the cell voltage deviation satisfies the voltage deviation diagnosis start condition.

In S310, when it is determined that the cell voltage deviation does not satisfy the voltage deviation diagnosis start condition, i.e., when tit is determined that the cell voltage deviation is less than the reference voltage deviation at S310-No, the battery diagnostic apparatus 500 may continue to monitor cell voltage at S300.

In S310, when it is determined that the cell voltage deviation satisfies the voltage deviation diagnosis start condition, i.e., it is determined that the cell voltage deviation is equal to or greater than the reference voltage deviation at S310-Yes, the battery diagnostic apparatus 500 may determines whether or not cell voltage Vc satisfies the normal voltage range at S320.

In S320, the battery diagnostic apparatus 500 may determine whether, among the plurality of cell voltages Vc, a minimum cell voltage Vc_min exceeds a lower limit threshold voltage or a maximum cell voltage Vc_max exceeds an upper limit threshold voltage.

In S320, when the minimum cell voltage Vc_min exceeds the lower limit threshold voltage or the maximum cell voltage Vc_max is less than the upper limit threshold voltage, the battery diagnostic apparatus 500 determines that cell voltage Vc satisfies the normal voltage range.

In S320, when it is determines that the cell voltage Vc does not satisfy the normal voltage range at S320-No, the battery diagnostic apparatus 500 may determine whether or not a situation where the cell voltage deviation satisfies the voltage deviation diagnosis start condition, i.e., a situation where the cell voltage deviation is equal to or greater than the reference voltage deviation, is maintained for the preset first reference time t_ref1 or more at S330.

At this time, the battery diagnostic apparatus 500 may operate the counter 530 and, on the basis of a count signal output from the counter 530, the situation where the cell voltage deviation is equal to or greater than the reference voltage deviation is maintained for the first reference time t_ref1 or more.

In S330, when it is determines that a situation where the cell voltage deviation is equal to or greater than the reference voltage deviation is maintained for less than the first reference time t_ref1 at S330-No, the battery diagnostic apparatus 500 may determines whether or not the cell voltage Vc satisfies the normal voltage range at S320.

In S330, when it is determines that a situation where the cell voltage deviation is equal to or greater than the reference voltage deviation is maintained for the first reference time t_ref1 or more at S330-Yes, the battery diagnostic apparatus 500 may diagnose that the voltage deviation occurs in the battery 200 at S340.

When the battery diagnostic apparatus 500 diagnoses the voltage deviation occurring in the battery 200, the battery diagnostic apparatus 500 may perform a following-up measure at S350.

In S350, the battery diagnostic apparatus 500 may limit output power of the battery 200 as the first power limit. Furthermore, the battery diagnostic apparatus 500 may provide a voltage deviation diagnosis result to the output part 600 and may allow the output part 600 to output an alarm corresponding to the voltage deviation diagnosis result. Furthermore, the battery diagnostic apparatus 500 may provide a voltage deviation diagnosis result to the controller 100 through the communication module 540.

In S320, when it is determines that the cell voltage Vc satisfies the normal voltage range at S320-Yes, the battery diagnostic apparatus 500 may determine whether or not a situation where the cell voltage deviation satisfies the voltage deviation diagnosis start condition, i.e., a situation where the cell voltage deviation is equal to or greater than the reference voltage deviation, is maintained for the preset second reference time t_ref2 or more at S360.

At this time, when the battery diagnostic apparatus 500 determines that the cell voltage Vc satisfies the normal voltage range, the processor 550 may operate the counter 530 and, on the basis of a count signal output from the counter 530, the situation where the cell voltage deviation is equal to or greater than the reference voltage deviation is maintained for the second reference time t_ref2 or more.

In S360, when it is determines that a situation where the cell voltage deviation is equal to or greater than the reference voltage deviation is maintained for less than the second reference time t_ref2 at S360-No, the battery diagnostic apparatus 500 may determines whether or not the cell voltage deviation is equal to or greater than the reference voltage deviation at S310.

In S360, when it is determines that a situation where the cell voltage deviation is equal to or greater than the reference voltage deviation is maintained for the second reference time t_ref2 or more at S360-Yes, the battery diagnostic apparatus 500 may diagnose that the voltage deviation occurs in the battery 200 at S370.

When the battery diagnostic apparatus 500 diagnoses the voltage deviation occurring in the battery 200, the battery diagnostic apparatus 500 may perform a following-up measure at S380.

In S380, the battery diagnostic apparatus 500 may limit output power of the battery 200 as the second power limit. Furthermore, the battery diagnostic apparatus 500 may provide a voltage deviation diagnosis result to the output part 600 and may allow the output part 600 to output an alarm corresponding to the voltage deviation diagnosis result. Furthermore, the battery diagnostic apparatus 500 may provide a voltage deviation diagnosis result to the controller 100 through the communication module 540.

In some implementations, in the technology for diagnosing a battery of a vehicle, when the cell voltage deviation satisfies the voltage deviation diagnosis start condition, the apparatus 500 for diagnosing a battery of a vehicle determines whether or not the cell voltage satisfies the normal voltage range, and may diagnose occurrence of a voltage deviation in the abnormal cell voltage or occurrence of a voltage deviation in the normal cell voltage according to a determined result.

In some implementations, when the cell voltage deviation is equal to or greater than the preset reference voltage deviation, the apparatus 500 for diagnosing a battery of a vehicle may determine whether or not the cell voltage satisfies the normal voltage range.

In some implementations, when the minimum cell voltage Vc_min exceeds the lower limit threshold voltage or the maximum cell voltage Vc_max is less than the upper limit threshold voltage, the apparatus 500 for diagnosing a battery of a vehicle determines that cell voltage Vc satisfies the normal voltage range.

In some implementations, in case where the cell voltage Vc does not satisfy the normal voltage range, when the apparatus 500 for diagnosing a battery of a vehicle determines that a situation where the cell voltage deviation satisfies the voltage deviation diagnosis start condition is maintained for the preset first reference time t_ref1 or more, the apparatus 500 can diagnose that a voltage deviation occurs in the battery 200.

In some implementations, in case where the cell voltage Vc satisfies the normal voltage range, when the apparatus 500 for diagnosing a battery of a vehicle determines that a situation where the cell voltage deviation satisfies the voltage deviation diagnosis start condition is maintained for the preset second reference time t_ref2 or more, the apparatus 500 can diagnose that a voltage deviation occurs in the battery 200.

In some implementations, when a voltage deviation occurs in the abnormal cell voltage and when a voltage deviation occurs in the normal cell voltage, the apparatus 500 for diagnosing a battery of a vehicle can limit output power of the battery as different power limits.

In some implementations, when a voltage deviation occurs in the normal cell voltage, limit power may have a value greater than a value of limit power when a voltage deviation occurs in the abnormal cell voltage.

1. An apparatus for diagnosing a battery of a vehicle, the apparatus comprising:
a voltage sensor configured to measure voltage of each of a plurality of battery cells within the battery; and
a processor configured to determine a voltage deviation with respect to the battery based on a cell voltage measured by the voltage sensor,
wherein the processor is configured to:
based on a cell voltage deviation satisfying a voltage deviation diagnosis start condition, determine whether the cell voltage is within a normal voltage range, and
based on a determination, determine a presence of a voltage deviation in abnormal cell voltage or normal cell voltage.

2. The apparatus of claim 1, the processor is configured to, based on the cell voltage deviation being equal to or greater than a preset reference voltage deviation, determine whether the cell voltage is within the normal voltage range.

3. The apparatus of claim 1, wherein the processor is configured to, based on (i) a minimum cell voltage exceeding a lower limit threshold voltage or (ii) a maximum cell voltage being less than an upper limit threshold voltage, determine that the cell voltage is within the normal voltage range.

4. The apparatus of claim 1, wherein the processor is configured to, based on (i) the cell voltage does not satisfying the normal voltage range and (ii) based on a determination that the cell voltage deviation satisfying the voltage deviation diagnosis start condition is maintained at or greater than a preset first reference time, determine occurrence of the voltage deviation within the battery.

5. The apparatus of claim 1, wherein the processor is configured to, based on (i) the cell voltage satisfying the normal voltage range and (ii) a determination that the cell voltage deviation satisfying the voltage deviation diagnosis start condition is maintained at or greater than a preset second reference time, determine occurrence of the voltage deviation within the battery.

6. The apparatus of claim 1, wherein the processor is configured to, based on the voltage deviation occurring in the abnormal cell voltage and the normal cell voltage, limit output power of the battery according to various power limits.

7. The apparatus of claim 6, wherein a power limit for the voltage deviation occurring in the normal cell voltage is greater than a power limit for the voltage deviation occurring in the abnormal cell voltage.

8. A vehicle battery diagnostic method performed by a processor based on a plurality of cell voltages measured by a voltage sensor, the battery diagnostic method comprising:
monitoring the plurality of cell voltages;
determining whether a cell voltage deviation satisfies a voltage deviation diagnosis start condition;
determining, based on the cell voltage deviation satisfying the voltage deviation diagnosis start condition, whether a cell voltage is within a normal voltage range; and
determining, based on a determination result, whether a presence of a voltage deviation in abnormal cell voltage or normal cell voltage.

9. The vehicle battery diagnostic method of claim 8, wherein determining whether the voltage deviation diagnosis start condition is satisfied comprises:
determining, based on the cell voltage deviation being equal to or greater than a preset reference voltage deviation, that the cell voltage deviation satisfies the voltage deviation diagnosis start condition.

10. The vehicle battery diagnostic method of claim 8, wherein determining whether the cell voltage is within the normal voltage range comprises:
determining, based on a minimum cell voltage exceeding a lower limit threshold voltage or a maximum cell voltage being less than an upper limit threshold voltage, that the cell voltage is within the normal voltage range.

11. The vehicle battery diagnostic method of claim 8, wherein determining the voltage deviation comprises:
determining, based on the cell voltage not being within the normal voltage range and the cell voltage deviation satisfying the voltage deviation diagnosis start condition being maintained at or greater than a preset first reference time, that the voltage deviation occurs within the battery.

12. The vehicle battery diagnostic method of claim 8, wherein determining the voltage deviation comprises:
determining, based on the cell voltage being within the normal voltage range and a determination that the cell voltage deviation satisfying the voltage deviation diagnosis start condition being maintained at or greater than a preset second reference time, that the voltage deviation occurs within the battery.

13. The vehicle battery diagnostic method of claim 8, further comprising:
limiting, based on a determination that the voltage deviation occurs in the abnormal cell voltage, output power of the battery as a first power limit, and
limiting based on a determination that the voltage deviation occurs in the normal cell voltage, output power of the battery as a second power limit.

14. The vehicle battery diagnostic method of claim 13, wherein the second power limit is greater the first power limit.

15. A vehicle system comprising:
a battery; and
a battery diagnostic apparatus;
wherein the battery diagnostic apparatus comprises:
a voltage sensor configured to measure voltage of each of a plurality of battery cells within the battery; and
a processor configured to determine a voltage deviation with respect to the battery based on a cell voltage measured by the voltage sensor,
wherein the processor is configured to:
based on a cell voltage deviation satisfying a voltage deviation diagnosis start condition, determine whether the cell voltage satisfies a normal voltage range, and
based on a determination result, determine a presence of a voltage deviation in abnormal cell voltage or normal cell voltage.
